(19) United States
(12) Patent Application Publication
(10) Pub. No.: US 2016/0035541 A1
(43) Pub. Date: Feb. 4, 2016

(54) PLASMA PROCESSING APPARATUS AND GAS SUPPLY MEMBER

(71) Applicant: TOKYO ELECTRON LIMITED, Tokyo (JP)

(72) Inventors: Shinichi KOZUKA, Miyagi (JP); Ryosuke NIITSUMA, Miyagi (JP); Manabu ISHIKAWA, Miyagi (JP)

(73) Assignee: TOKYO ELECTRON LIMITED, Tokyo (JP)

(21) Appl. No.: 14/813,207

(22) Filed: Jul. 30, 2015

(30) Foreign Application Priority Data
Jul. 31, 2014 (JP) 2014-157151
Jul. 7, 2015 (JP) 2015-136299

(51) Int. Cl. H01J 37/32

(52) U.S. Cl. CPC H01J 37/3244; H01J 37/32009; H01J 37/32715

(57) ABSTRACT

Disclosed is a plasma processing apparatus including: a processing container; a support member provided within the processing container and configured to support a processing target substrate; and a gas supply member including a first region formed with a gas supply hole, a second region not formed with a gas supply hole, and a third region formed with a gas supply holes. The first to third regions are disposed sequentially from a central portion side of the processing target substrate along a radial direction of the processing target substrate, and the plasma processing apparatus is processed to introduce a processing gas from the gas supply holes of the gas supply member for plasma processing of the processing target substrate into the processing container.

### CROSS-REFERENCE TO RELATED APPLICATIONS

This application is based on and claims priority from Japanese Patent Application Nos. 2014-157151, and 2015-136299 filed on Jul. 31, 2014, and Jul. 7, 2015 with the Japan Patent Office, the disclosures of which are incorporated herein in their entirety by reference.

### TECHNICAL FIELD

Various aspects and exemplary embodiments of the present disclosure are related to a plasma processing apparatus and a gas supply member.

### BACKGROUND

In a semiconductor manufacturing process, a plasma processing apparatus configured to perform a plasma processing is widely used for the purpose of, for example, deposition or etching of a thin film. As for the plasma processing apparatus, for example, a plasma chemical vapor deposition (CVD) apparatus configured to perform a deposition processing of a thin film, or a plasma etching apparatus configured to perform an etching processing may be exemplified.

The plasma processing apparatus includes, for example, a processing container that defines a plasma processing space, a support member configured to support a processing target substrate within the processing container, and a gas supply member configured to supply a processing gas required for a plasma reaction into a processing chamber. The gas supply member includes gas supply holes, and introduces the processing gas from the gas supply holes into the processing container.

Here, the gas supply member may be divided into a plurality of regions having different numbers of gas supply holes. For example, it is known that the gas supply member is divided into a central region corresponding to a central portion of the processing target substrate, and a periphery region corresponding to a periphery portion of the processing target substrate, and different numbers of gas supply holes are formed in the central region and the periphery region, respectively. See, for example, Japanese Patent Laid-Open Publication No. 2008-244142.

### SUMMARY

The present disclosure provides a plasma processing apparatus. The plasma processing apparatus includes: a processing container; a support member provided within the processing container and configured to support a processing target substrate; and a gas supply member including a first region formed with a gas supply hole, a second region not formed with a gas supply hole, and a third region formed with a gas supply hole. The first region, the second region, and the third region are disposed sequentially from a central portion side of the processing target substrate along a radial direction of the processing target substrate. The plasma processing apparatus are processed to introduce a processing gas from the gas supply holes of the gas supply member for plasma processing of the processing target substrate into the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic sectional view illustrating a plasma etching apparatus as a plasma processing apparatus according to a first exemplary embodiment.

FIG. 2 is a view illustrating an example of a structure of a shower head in the first exemplary embodiment.

FIG. 3 is a plan view of an electrode plate illustrated in FIG. 2.

FIG. 4A illustrates a streamline distribution of a processing gas with respect to a radial position of a wafer when the flow of the processing gas on the wafer was simulated using a plasma etching apparatus in which a region not formed with gas supply holes is not provided in the electrode plate.

FIG. 4B illustrates a flow velocity distribution of a processing gas with respect to a radial position of a wafer when the flow of the processing gas on the wafer was simulated using a plasma etching apparatus in which a region not formed with the gas supply holes is not provided in the electrode plate.

FIG. 5A illustrates a streamline distribution of a processing gas with respect to a radial position of a wafer when the flow of the processing gas on the wafer was simulated using the plasma etching apparatus of the first exemplary embodiment.

FIG. 5B illustrates a flow velocity distribution of a processing gas with respect to a radial position of a wafer when the flow of the processing gas on the wafer was simulated using the plasma etching apparatus of the first exemplary embodiment.

FIG. 6 is a view illustrating a simulation result on a pressure distribution of the processing gas in the plasma etching apparatus according to the first exemplary embodiment.

FIG. 7 is a view illustrating an effect (an actual measurement result of an etching rate) caused by the plasma etching apparatus according to the first exemplary embodiment.

FIG. 8 is a vertical sectional view of an electrode plate in a second exemplary embodiment.

FIG. 9A illustrates a streamline distribution of a processing gas with respect to a radial position of a wafer when the flow of the processing gas on the wafer was simulated using a plasma etching apparatus of the second exemplary embodiment.

FIG. 9B illustrates a flow velocity distribution of a processing gas with respect to a radial position of a wafer when the flow of the processing gas on the wafer was simulated using the plasma etching apparatus of the second exemplary embodiment.

FIG. 10 is a view illustrating a simulation result on a pressure distribution of the processing gas in the plasma etching apparatus according to the second exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the conventional technology described above, the controllability of a pressure distribution of a processing gas in a central portion and a periphery portion on a processing target substrate is relatively poor. Thus, there is a problem in that it is difficult to improve the controllability of an etching rate along a radial direction of the processing target substrate.

According to one aspect, a plasma processing apparatus disclosed herein includes: a processing container; a support member provided within the processing container and configured to support a processing target substrate; and a gas supply member including a first region formed with a gas supply hole, a second region not formed with a gas supply hole, and a third region formed with a gas supply hole. The first region, the second region, and the third region are disposed sequentially from a central portion side of the processing target substrate along a radial direction of the processing target substrate. The plasma processing apparatus is processed to introduce a processing gas from the gas supply holes of the gas supply member for plasma processing of the processing target substrate into the processing container.

According to one exemplary embodiment, in the plasma processing apparatus disclosed herein, the gas supply hole formed in the third region is disposed at a position outside a position inwardly spaced apart from a periphery of the processing target substrate by 10 mm along the radial direction of the processing target substrate.

According to one exemplary embodiment, in the plasma processing apparatus disclosed herein, the gas supply hole formed in the third region is disposed in a range from a position inwardly spaced apart from a periphery of the processing target substrate by 10 mm to a position outwardly spaced apart from the periphery of the processing target substrate by 10 mm along the radial direction of the processing target substrate.

According to one exemplary embodiment, in the plasma processing apparatus disclosed herein, the gas supply hole formed in the third region is disposed at a position outside or on a periphery of the processing target substrate.

According to one exemplary embodiment, in the plasma processing apparatus disclosed herein, the gas supply hole formed in the third region has an inclined portion that is inclined with respect to a central axis of the processing target substrate so that a distance along the radial direction of the processing target substrate from the central axis of the processing target substrate is increased as the inclined portion gets closer to the processing target substrate.

According to another aspect, a gas supply member disclosed herein is configured to supply a processing gas into a processing container in which a processing target substrate is disposed. The gas supply member includes: a first gas supply region disposed at a center portion side with respect to a central line between a central portion and an edge portion of the gas supply member, and formed with a plurality of first gas supply holes; a second gas supply region disposed at an edge portion side with respect to the central line between the central portion and an edge portion of the gas supply member, and formed with a second gas supply hole; and a non-gas supply region disposed between the first gas supply region and the second gas supply region, and not formed with a gas supply hole.

According to one exemplary embodiment, in the gas supply member disclosed herein, the second gas supply hole is disposed at a position outside or on a periphery of the processing target substrate.

According to one exemplary embodiment, in the gas supply member disclosed herein, the second gas supply hole has an inclined portion that is inclined with respect to a central axis of the processing target substrate so that a distance along the radial direction of the processing target substrate from the central axis of the processing target substrate is increased as the inclined portion gets closer to the processing target substrate.

According to an aspect of the disclosed plasma processing apparatus, the controllability of an etching rate along a radial direction of a processing target substrate can be improved.

Hereinafter, exemplary embodiments of a plasma processing apparatus and a gas supply member disclosed herein will be described with reference to accompanying drawings.

### First Exemplary Embodiment

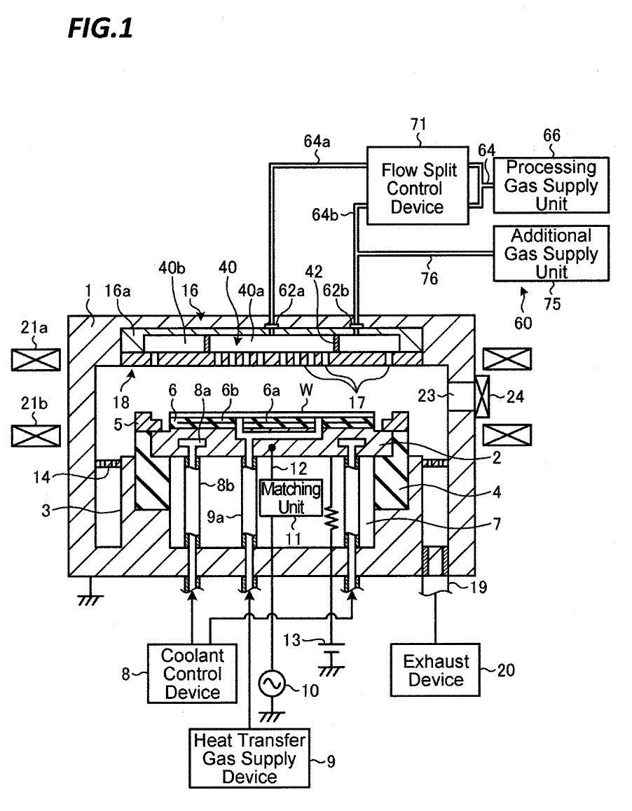

FIG. 1 is a schematic sectional view illustrating a plasma etching apparatus as a plasma processing apparatus according to a first exemplary embodiment. The plasma etching apparatus is configured as a capacitively-coupled parallel plate plasma etching apparatus, and has an aluminum-made chamber 1 that is airtightly configured in a substantially cylindrical shape, and has a wall portion that has, for example, an anodized surface. The chamber 1 is grounded. The chamber 1 corresponds to an example of a processing container.

Within the chamber 1, a support table 2 is provided to horizontally support a semiconductor wafer (hereinafter, simply referred to as a “wafer”) W that is a processing target substrate and to serve as a lower electrode. The support table 2 corresponds to an example of a support member. The support table 2 is made of, for example, aluminum, of which the surface is anodized. The support table 2 is supported on a support portion 3 protruding from the bottom wall of the chamber 1 through an insulating member 4. A focus ring 5 made of a conductive material or an insulating material is provided at the outer periphery above the support table 2. A baffle plate 14 is provided at the outer periphery outside the focus ring 5.

An electrostatic chuck 6 is provided on the front surface of the support table 2 to electrostatically attract the wafer W. The electrostatic chuck 6 has a configuration with an electrode 6a being sandwiched between insulators 6b, and the insulators 6b are made of, for example, a dielectric substance such as alumina: The electrode 6a is connected with a DC power source 13. When a voltage is applied to the electrode 6a from the DC power source 13, the wafer W is attracted by, for example, Coulomb force.

A coolant flow path 8a is provided within the support table 2, and a coolant pipe 8b is connected to the coolant flow path 8a. A proper coolant is supplied to the coolant flow path 8a through the coolant pipe 8b by a coolant control device 8 to be circulated. Accordingly, the support table 2 is controllable at an appropriate temperature. Also, a heat transfer gas pipe 9a is provided to supply a heat transfer gas for transferring a heat, for example, He gas, to a space between the front surface of the electrostatic chuck 6 and the rear surface of the wafer W so that the heat transfer gas is supplied to the rear surface of the wafer W from a heat transfer gas supply device 9 through the heat transfer gas pipe 9a. Accordingly, even if the inside of the chamber 1 is exhausted and maintained under vacuum, the cold heat of the coolant circulated in the coolant flow path 8a may be efficiently transferred to the wafer W so as to improve the temperature controllability of the wafer W.

A power feeding line 12 is connected to substantially the center of the support table 2 to supply a high frequency power, and a matching unit 11 and a high frequency power supply 10 are connected to the power feeding line 12. From the high frequency power supply 10, a high frequency power having a predetermined frequency of, for example, 10 MHz or more is supplied to the support table 2. Meanwhile, above the support table 2 serving as the lower electrode, a shower head 16 to be described below that faces the support table 2 in parallel is provided, and the shower head 16 is grounded through the chamber 1. Accordingly, the shower head 16 serves as an upper electrode to constitute a pair of parallel plat panel electrodes, together with the support table 2.

An exhaust pipe 19 is connected to the bottom wall of the chamber 1, and an exhaust device 20 including, for example, a vacuum pump is connected to the exhaust pipe 19. The inside of the chamber 1 may be decompressed to a desired vacuum degree by operating the vacuum pump of the exhaust device 20. Meanwhile, a gate valve 24 is provided at the upper portion of the side wall of the chamber 1 to open and close a carry-in/out port 23 of the wafer W.

Meanwhile, two ring magnets 21a and 21b are concentrically disposed to surround the chamber 1 above and below the carry-in/out port 23 of the chamber 1 so that a magnetic field is formed around a processing space between the support table 2 and the shower head 16. The ring magnets 21a and 21b are provided to be rotatable by a rotation mechanism (not illustrated). Also, the ring magnets may not be provided.

The plasma etching apparatus illustrated in FIG. 1 includes the shower head 16 configured to eject a processing gas for plasma processing of the wafer W to the wafer W supported by the support table 2, and a gas supply device 60 configured to supply the processing gas to the shower head 16.

The shower head 16 includes a shower head body 16a and a circular electrode plate 18 that is exchangeably provided on the rear surface of the shower head body 16a. The shower head body 16a is formed in a disk shape having the same diameter as the electrode plate 18. A circular gas diffusion space 40 is formed within the shower head body 16a. Gas supply holes 17 are provided in the electrode plate 18 so as to introduce the processing gas into the chamber 1.

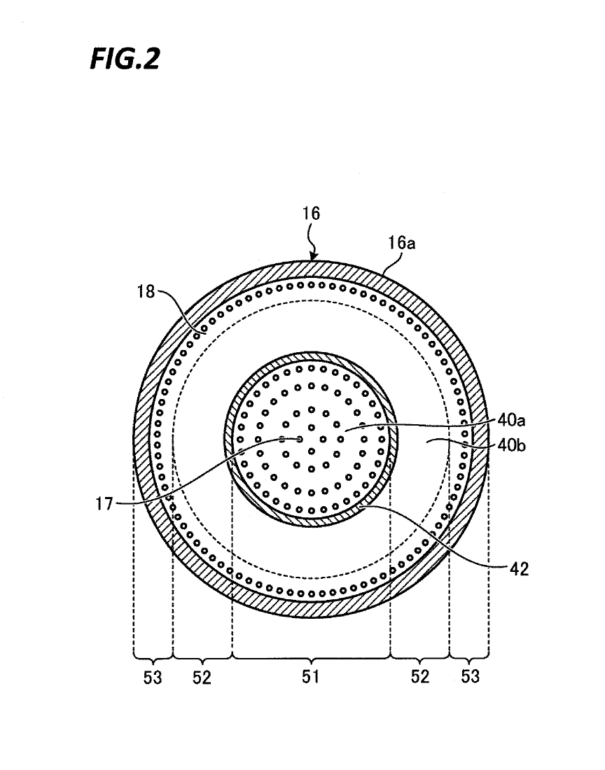

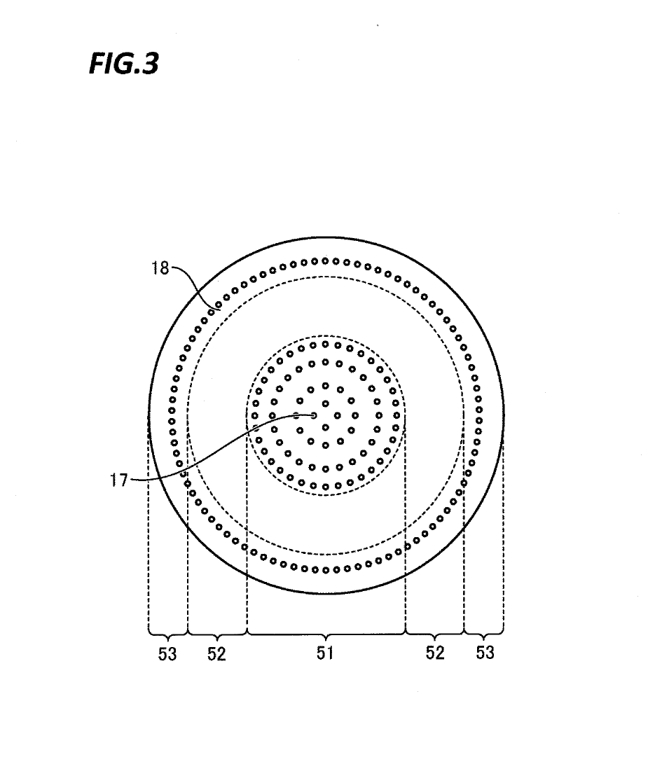

FIG. 2 is a view illustrating an example of a structure of a shower head in the first exemplary embodiment. FIG. 3 is a plan view of an electrode plate illustrated in FIG. 2. As illustrated in FIGS. 1 and 2, the gas diffusion space 40 is divided into a first gas diffusion chamber 40a at the central side and a second gas diffusion chamber 40b at the outside by an annular partition wall member 42 formed of, for example, an 0 ring. The gas diffusion chamber may be divided into three or more zones. The processing gas is supplied to the first gas diffusion chamber 40a and the second gas diffusion chamber 40b by the gas supply device 60.

As illustrated in FIGS. 2 and 3, the electrode plate 18 is divided into a first region 51 formed with the gas supply holes 17, a second region 52 not formed with the gas supply holes 17, and a third region 53 formed with the gas supply holes 17. The electrode plate 18 corresponds to an example of a gas supply member. The first region 51, the second region 52, and the third region 53 are disposed sequentially from the central side of the wafer W along the radial direction of the wafer W.

The first region 51 is disposed at a location corresponding to the first gas diffusion chamber 40a. That is, the first region 51 is disposed at a central portion side with respect to a central line between the central position and an edge portion of the electrode plate 18. The first region 51 is formed with a plurality of gas supply holes 17. The first region 51 is an example of a first gas supply region. The first region 51 ejects the processing gas supplied to the first gas diffusion chamber 40a to a space between the shower head 16 and the support table 2 from the gas supply holes 17.

The second region 52 and the third region 53 are disposed at a location corresponding to the second gas diffusion chamber 40b. That is, the third region 53 is disposed at an edge portion side with respect to the central line between the central position and the edge portion of the electrode plate 18, and the second region 52 is disposed between the first region 51 and the third region 53. The third region 53 is an example of a second gas supply region, and the second region 52 is an example of a non-gas supply region. The second region 52 has a rectifying function that guides the processing gas supplied to the second gas diffusion chamber 40b to the gas supply holes 17 formed in the third region 53. The third region 53 ejects the processing gas supplied to the second gas diffusion chamber 40b, together with the processing gas guided to the gas supply holes 17 by the rectifying function of the second region 52, from the gas supply holes 17 to the space between the shower head 16 and the support table 2.

Here, descriptions will be made on the relationship between the flow of the processing gas ejected from the gas supply holes 17 of the first region 51, the flow of the processing gas ejected from the gas supply holes 17 of the third region 53, and the flow of the processing gas at a location corresponding to the second region 52. In the following description, the processing gas ejected from the gas supply holes 17 of the first region 51 will be properly referred to as a “first processing gas,” and the processing gas ejected from the gas supply holes 17 of the third region 53 will be properly referred to as a “second processing gas.” The first processing gas ejected from the gas supply holes 17 of the first region 51 to the space between the shower head 16 and the support table 2 flows in an exhaust direction [a direction in which the exhaust device 20 is connected]. The first processing gas flowing in the exhaust direction collides with the second processing gas ejected from the gas supply holes 17 of the third region 53 to the space between the shower head 16 and the support table 2. The second processing gas that is ejected from the gas supply holes 17 of the third region 53 to the space between the shower head 16 and the support table 2 is mixed with the processing gas guided to the gas supply holes 17 by rectifying function of the second region 52. Therefore, the flow velocity of the second processing gas ejected from the gas supply holes 17 of the third region 53 to the space between the shower head 16 and the support table 2 is locally increased so that the second processing gas forms an airflow wall which interferes with the first processing gas flowing in the exhaust direction. Then, the speed of the first processing gas flowing in the exhaust direction is decreased in the space present at the location corresponding to the second region 52 interposed between the third region 53 and the first region 51, in the space between the shower head 16 and the support table 2. Accordingly, the processing gas stays in the space present at the location corresponding to the second region 52 interposed between the third region 53 and the first region 51. As a result, plasma etching using the processing gas is facilitated in the space present at the location corresponding to the second region 52 interposed between the third region 53 and the first region 51, in the space between the shower head 16 and the support table 2.

The gas supply holes 17 formed in the third region 53 may be disposed at a location where the processing gas is efficiently ejected to the periphery of the wafer W. The gas supply holes 17 formed in the third region 53 may be disposed at a position outside a position inwardly spaced apart from the periphery of the wafer W by 10 mm along the radial direction of the wafer W. The gas supply holes 17 formed in the third region 53 may be disposed in a range from a position inwardly spaced apart from the periphery of the wafer W by 10 mm to a position outwardly spaced apart from the periphery of the wafer W by 10 mm along the radial direction of the wafer W.

The location of the gas supply holes 17 formed in the third region 53 is not limited to the location described above. For example, the gas supply holes 17 formed in the third region 53 may be disposed at a location outside of the periphery of the wafer W or at a location on the periphery of the wafer W.

The gas supply device 60 includes a processing gas supply unit 66 configured to supply the processing gas, an additional gas supply unit 75 configured to supply an additional gas to be added to the processing gas, and a flow split control device 71. A gas supply pipe 64 extending from the processing gas supply unit 66 diverges into two branch pipes 64a and 64b on the way to be connected to gas introducing ports 62a and 62b formed in the shower head body 16a. The processing gas from the gas introducing ports 62a and 62b reaches the first gas diffusion chamber 40a and the second gas diffusion chamber 40b. The partial flow rates of the branch pipes 64a and 64b are adjusted by the flow split control device 71 provided on the way.

Also, an additional gas is supplied to the second gas diffusion chamber 40b from the additional gas supply unit 75 so as to adjust the property of etching by the processing gas. The additional gas exerts a predetermined effect during the etching in order to, for example, uniformly perform the etching processing. A gas supply tube 76 extending from the additional gas supply unit 75 is connected to the branch pipe 64b. The additional gas reaches the second gas diffusion chamber 40b through the gas supply tube 76, the branch pipe 64b and the gas introducing port 62b.

As described above, in the first exemplary embodiment, the first region 51 formed with the gas supply holes 17, the second region 52 not formed with the gas supply holes 17, and the third region 53 formed with the gas supply holes 17 are disposed sequentially from the central side of the wafer W along the radial direction of the wafer W, in the electrode plate 18 as for the gas supply member. Accordingly, the processing gas is efficiently supplied from the gas supply holes 17 of the first region 51 to the central side of the wafer W, and the processing gas is efficiently supplied from the gas supply holes 17 of the third region 53 to the periphery side of the wafer W. Also, the plasma etching using the processing gas is facilitated in the space present at the location corresponding to the second region 52 interposed between the third region 53 and the first region 51. As a result, according to the first exemplary embodiment, the controllability of the etching rate along the radial direction of the wafer W may be improved.

Hereinafter, descriptions will be made on a simulation result by the plasma etching apparatus according to the first exemplary embodiment (a simulation result of a flow velocity distribution of the processing gas, and a simulation result of a pressure distribution of the processing gas).

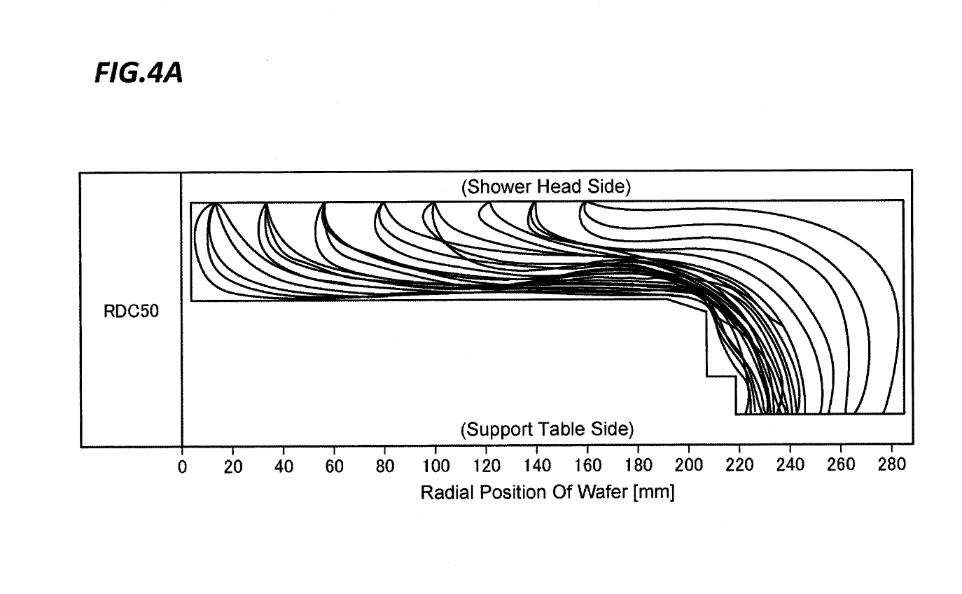

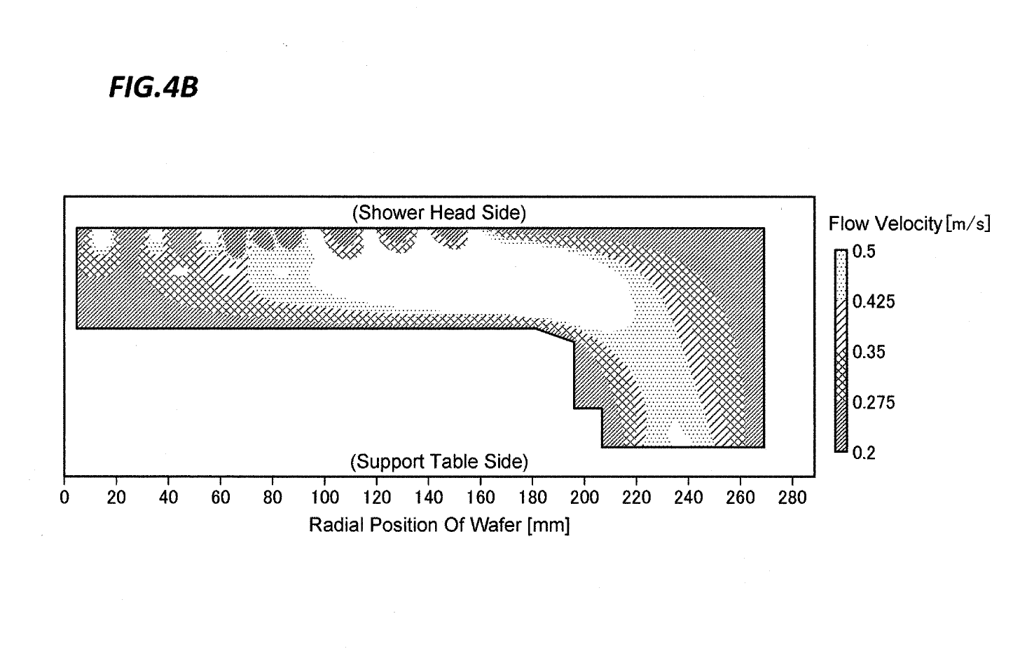

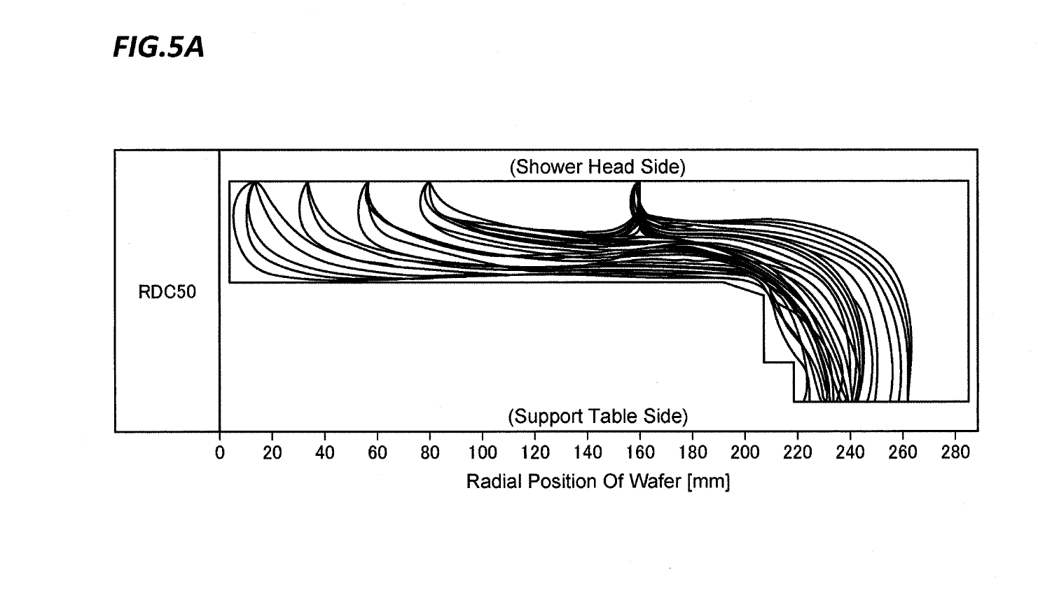

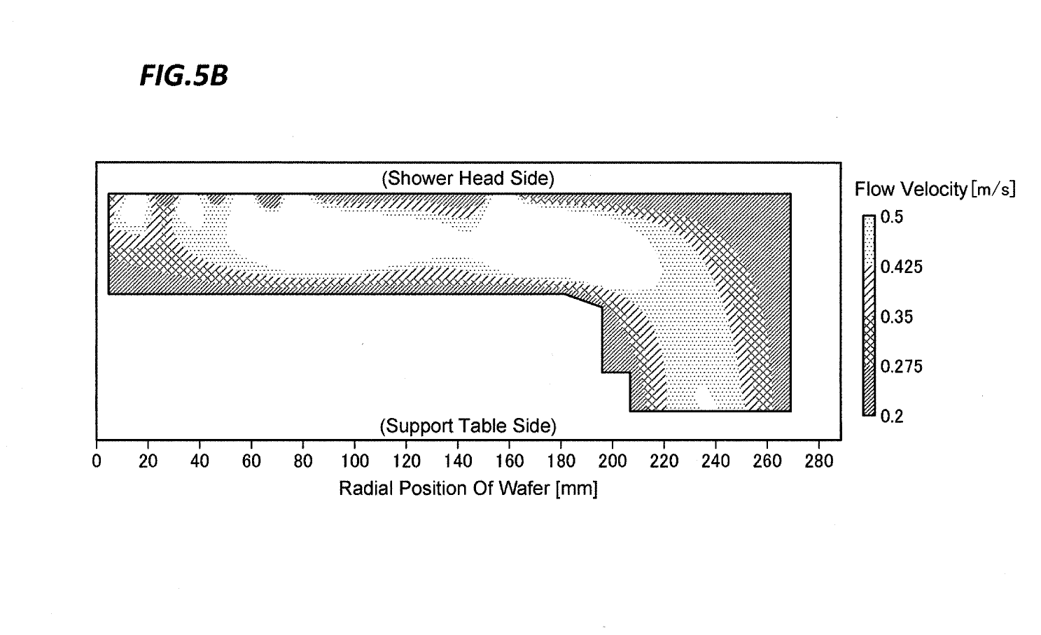

First, a simulation result of a flow velocity distribution of the processing gas will be described. FIG. 4A illustrates a streamline distribution of a processing gas with respect to a radial position of a wafer when the flow of the processing gas on the wafer was simulated using a plasma etching apparatus in which a region not formed with the gas supply holes 17 is not provided in the electrode plate 18. FIG. 4B illustrates a flow velocity distribution of a processing gas with respect to a radial position of a wafer when the flow of the processing gas on the wafer was simulated using a plasma etching apparatus in which a region not formed with the gas supply holes 17 is not provided in the electrode plate 18. FIG. 5A illustrates a streamline distribution of a processing gas with respect to a radial position of a wafer when the flow of the processing gas on the wafer was simulated using the plasma etching apparatus of the first exemplary embodiment. FIG. 5B illustrates a flow velocity distribution of a processing gas with respect to a radial position of a wafer when the flow of the processing gas on the wafer was simulated using the plasma etching apparatus of the first exemplary embodiment.

As for the simulation condition (parameter) in FIGS. 4A and 4B, a wafer with a radius of 150 mm was used, and the electrode plate 18 was divided into eight zones (Zones 1 to 8) along the radial direction from the center of the electrode plate 18 so that the processing gas was ejected from all zones to obtain the streamline distribution of the processing gas and the flow velocity distribution of the processing gas. Also, in the simulation of FIGS. 4A and 4B, as for the gas supply holes 17 corresponding to Zone 1, four gas supply holes 17 were disposed on a circumference having a radius of 10 mm from the center of the electrode plate 18. As for the gas supply holes 17 corresponding to Zone 2, 12 gas supply holes 17 were disposed on a circumference having a radius of 30 mm from the center of the electrode plate 18. As for the gas supply holes 17 corresponding to Zone 3, 24 gas supply holes 17 were disposed on a circumference having a radius of 50 mm from the center of the electrode plate 18. As for the gas supply holes 17 corresponding to Zone 4, 36 gas supply holes 17 were disposed on a circumference having a radius of 70 mm from the center of the electrode plate 18. As for the gas supply holes 17 corresponding to Zone 5, 48 gas supply holes 17 were disposed on a circumference having a radius of 90 mm from the center of the electrode plate 18. As for the gas supply holes 17 corresponding to Zone 6, 60 gas supply holes 17 were disposed on a circumference having a radius of 110 mm from the center of the electrode plate 18. As for the gas supply holes 17 corresponding to Zone 7, 80 gas supply holes 17 were disposed on a circumference having a radius of 130 mm from the center of the electrode plate 18. As for the gas supply holes 17 corresponding to Zone 8, 100 gas supply holes 17 were disposed on a circumference having a radius of 150 mm from the center of the electrode plate 18.

In contrast, as for the simulation condition in FIGS. 5A and 5B, a wafer with a radius of 150 mm was used, and among Zones 1 to 8 described above, Zones 5 to 7 were closed. The processing gas was ejected from Zones 1 to 4 and Zone 8 to obtain the streamline distribution of the processing gas and the flow velocity distribution of the processing gas. That is, in the simulation of FIGS. 5A and 5B, Zones 5 to 7 correspond to the second region 52 not formed with the gas supply holes 17.

In FIGS. 4A and 4B and FIGS. 5A and 5B, the horizontal axis indicates a radial position [mm] of a wafer with respect to the center (0 mm) of the wafer with a radius of 150 mm.

In FIGS. 4A and 4B and FIGS. 5A and 5B, other simulation conditions are as follows: a processing gas:CF₄-150 sccm, a pressure within a chamber: 40 mTorr, and RDC: 50. A radial distribution control (RDC) is a technology of controlling a branch ratio of a common gas by a flow splitter, and controlling gas introduction amounts from a central introduction port and a peripheral introduction portion, that is, a ratio of a flow rate of a processing gas to be supplied to the first gas diffusion chamber 40a, to a flow rate of a processing gas to be supplied to the second gas diffusion chamber 40b.

From the comparison between FIG. 4A and FIG. 5A, the following phenomenon was found. That is, unlike in the apparatus in which a region not formed with the gas supply holes 17 is not provided in the electrode plate 18, in the apparatus of the first exemplary embodiment in which the second region 52 not formed with the gas supply holes 17 is provided, the processing gas ejected from the gas supply holes 17 corresponding to Zone 8 formed an airflow wall which interferes with the processing gas that is ejected from the gas supply holes 17 corresponding to Zones 1 to 4 and flows in the exhaust direction.

From the comparison between FIG. 4B and FIG. 5B, the following phenomenon was found. That is, unlike in the apparatus in which a region not formed with the gas supply holes 17 is not provided in the electrode plate 18, in the apparatus of the first exemplary embodiment in which the second region 52 not formed with the gas supply holes 17 is provided, the speed of the processing gas flowing in the exhaust direction was decreased in a space present at a location corresponding to the second region 52, in a space between the shower head 16 and the support table 2. Accordingly, in the apparatus of the first exemplary embodiment in which the second region 52 not formed with the gas supply holes 17 is provided, the processing gas stays in the space present at the location corresponding to the second region 52. This indicates that retention of a gas flow is formed. That is, in the space present at the location corresponding to the second region 52, the airflow wall formed by the processing gas ejected from the gas supply holes 17 corresponding to Zone 8 interferes with the flow of the processing gas. Accordingly, it is assumed that the retention increases the concentration of the processing gas (etchant gas), and facilitates plasma etching using the processing gas in the space present at the location corresponding to the second region 52 in the space between the shower head 16 and the support table 2. As a result, in the apparatus of the first exemplary embodiment in which the second region 52 not formed with the gas supply holes 17 is provided, it is assumed that it is possible to improve the controllability (margin width) of the etching rate along the radial direction of the wafer W.

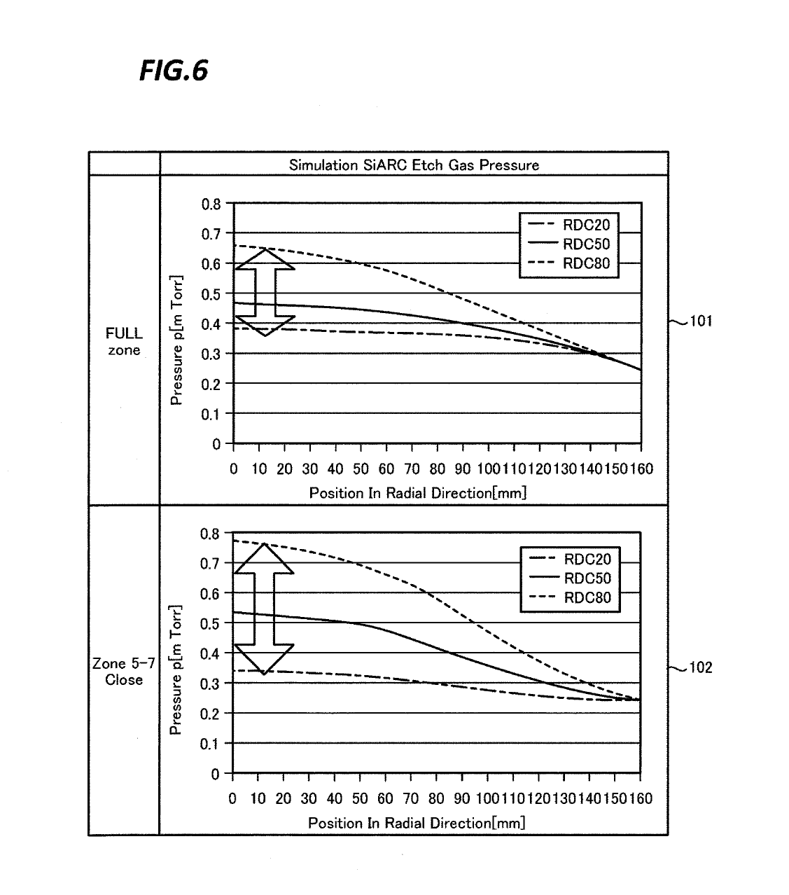

Subsequently, descriptions will be made on a simulation result of a pressure distribution of a processing gas. FIG. 6 is a view illustrating a simulation result on a pressure distribution of the processing gas in the plasma etching apparatus according to the first exemplary embodiment. FIG. 6 includes a graph 101 and a graph 102.

The graph 101 illustrates a simulation result when a pressure distribution of a processing gas on a wafer was simulated using a plasma etching apparatus in which a region not formed with the gas supply holes 17 is not provided in the electrode plate 18. The graph 102 illustrates a simulation result when a pressure distribution of a processing gas on a wafer was simulated using the plasma etching apparatus of the first exemplary embodiment. In the graphs 101 and 102, the vertical axis indicates a pressure [mTorr] at a position 5 mm above the front surface of the wafer. In the graphs 101 and 102, the horizontal axis indicates a radial position [mm] of a wafer with respect to the center (0 mm) of the wafer. In the graphs 101 and 102, the RDC indicates a ratio of a flow rate of a processing gas to be supplied to the first gas diffusion chamber 40a, to a flow rate of a processing gas to be supplied to the second gas diffusion chamber 40b.

Other simulation conditions are the same as those used in FIGS. 4A and 4B and FIGS. 5A and 5B.

As illustrated in FIG. 6, unlike in the apparatus in which a region not formed with the gas supply holes 17 is not provided in the electrode plate 18, in the apparatus of the first exemplary embodiment in which the second region 52 not formed with the gas supply holes 17 is provided, the control width of the pressure distribution of the processing gas was increased in the central portion and the periphery portion of the wafer. That is, it was found that as in the apparatus of the first exemplary embodiment, when the first region 51 formed with the gas supply holes 17, the second region 52 not formed with the gas supply holes 17, and the third region 53 formed with the gas supply holes 17 are disposed on the electrode plate 18 sequentially from the central side of the wafer W along the radial direction of the wafer W, the controllability (margin width) of the pressure distribution of the processing gas is improved.

From the simulation result described above, it was assumed that when the second region 52 not formed with the gas supply holes 17 is provided, the controllability of the etching rate along the radial direction of the wafer W may be improved. Therefore, the inventors actually measured the etching rate along the radial direction of the wafer W using the plasma etching apparatus according to the first exemplary embodiment.

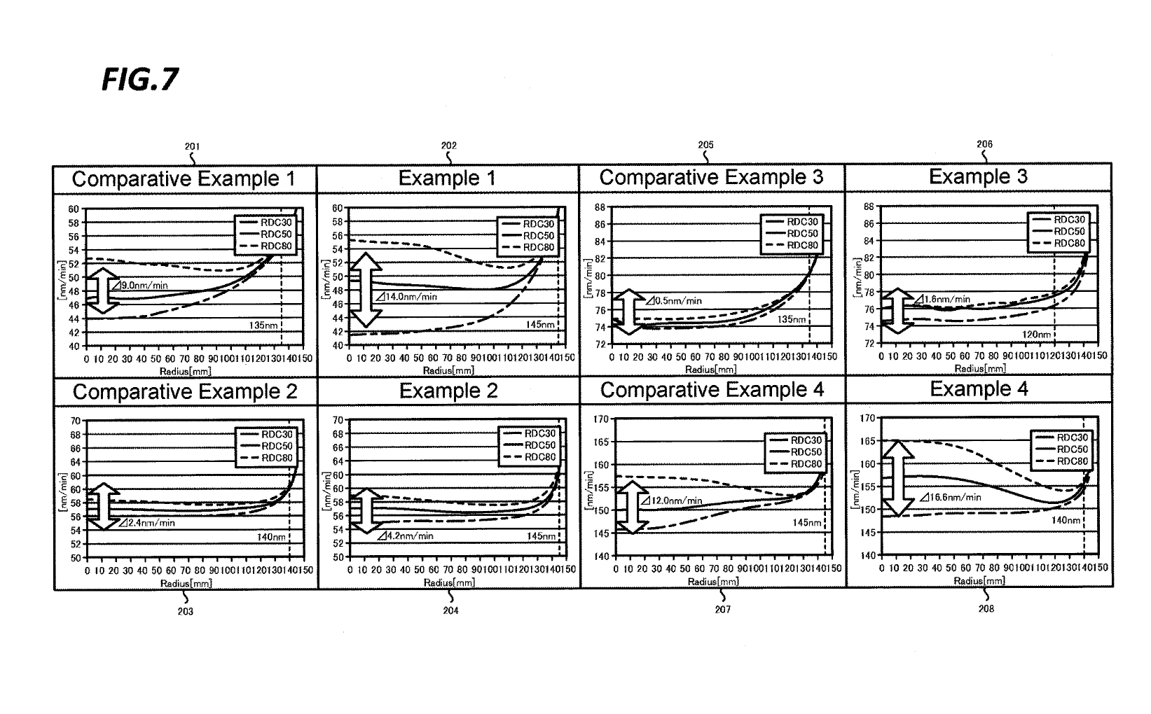

Hereinafter, descriptions will be made on the effect caused by the plasma etching apparatus according to the first exemplary embodiment (the actual measurement result of the etching rate). FIG. 7 is a view illustrating the effect (the actual measurement result of the etching rate) caused by the plasma etching apparatus according to the first exemplary embodiment. FIG. 7 includes graphs 201 to 208.

The graphs 201, 203, 205 and 207 illustrate actual measurement results when the distribution of an etching rate of a wafer was actually measured using a plasma etching apparatus in which a region not formed with the gas supply holes 17 is not provided in the electrode plate 18 (Comparative Examples 1 to 4). The graphs 202, 204, 206 and 208 illustrate results when the distribution of an etching rate of a wafer was actually measured using a plasma etching apparatus of the first exemplary embodiment (Examples 1 to 4). In the graphs 201 to 208, the vertical axis indicates an etching rate [nm/min] of a wafer. In the graphs 201 to 208, the horizontal axis indicates a radial position [mm] of a wafer with respect to the center position (0 mm) of the wafer. Also, in the graphs 201 to 208, the RDC indicates a ratio of a flow rate of a processing gas to be supplied to the first gas diffusion chamber 40a, to a flow rate of a processing gas to be supplied to the second gas diffusion chamber 40b.

It is assumed that between a pair of Comparative Example 1 and Example 1, a pair of Comparative Example 2 and Example 2, a pair of Comparative Example 3 and Example 3, and a pair of Comparative Example 4 and Example 4, the kinds and flow rates of a processing gas used for the plasma processing, or the kinds of a film on the wafer are different from each other.

As illustrated in FIG. 7, in Comparative Example 1 in which a region not formed with the gas supply holes 17 is not provided in the electrode plate 18, the control width of an etching rate at the center of the wafer was 9.0 nm/min, and a position where the etching rate was fixed was 135 mm.

In contrast, in Example 1 in which the second region 52 not formed with the gas supply holes 17 is provided in the electrode plate 18, the control width of an etching rate at the center of the wafer was 14.0 nm/min, and a position where the etching rate was fixed was 145 nm. That is, it was found that as compared to that in Comparative Example 1, the controllability of an etching rate along the radial direction of the wafer W may be improved in Example 1.

Likewise, it was found that as compared to that in Comparative Examples 2 to 4, respectively, the controllability of an etching rate along the radial direction of the wafer W may also be improved in Examples 2 to 4.

### Second Exemplary Embodiment

Hereinafter, a plasma etching apparatus according to a second exemplary embodiment will be described. The plasma etching apparatus according to the second exemplary embodiment is different from the plasma etching apparatus according to the first exemplary embodiment in the shape of the gas supply holes 17 formed in the third region 53 of the electrode plate 18, but other elements thereof are the same as those of the plasma etching apparatus according to the first exemplary embodiment. Accordingly, hereinafter, descriptions on the same configuration as that of the first exemplary embodiment will be omitted.

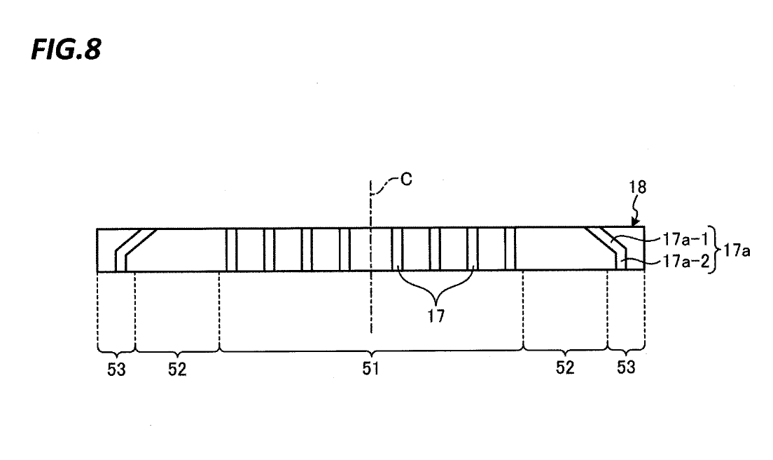

FIG. 8 is a vertical sectional view of an electrode plate in the second exemplary embodiment. In the example of FIG. 8, it is assumed that the central axis C of the wafer W coincides with the central axis of the electrode plate 18. Also, in the example of FIG. 8, it is assumed that the rear surface of the electrode plate 18 faces the wafer W. As illustrated in FIG. 8, the electrode plate 18 in the second exemplary embodiment is divided into a first region 51 formed with gas supply holes 17, a second region 52 not formed with the gas supply holes 17, and a third region 53 formed with the gas supply holes 17 in the same manner as in the electrode plate 18 in the first exemplary embodiment. The electrode plate 18 corresponds to an example of a gas supply member. The first region 51, the second region 52, and the third region 53 are disposed sequentially from the central side of the wafer W along the radial direction of the wafer W. Hereinafter, the gas supply holes 17 formed in the third region 53 will be properly referred to as “gas supply holes 17a.”

Each of the gas supply holes 17a includes an inclined portion 17a-1 and a non-inclined portion 17a-2 sequentially from the top side along the thickness direction of the electrode plate 18. The inclined portion 17a-1 is inclined with respect to the central axis C of the wafer W so that a distance along the radial direction of the wafer W from the central axis C of the wafer W is increased as the inclined portion 17a-1 gets closer to the wafer W. The non-inclined portion 17a-2 is not inclined with respect to the central axis C of the wafer W.

Here, descriptions will be made on the relationship between the flow of the processing gas ejected from the gas supply holes 17 of the first region 51, the flow of the processing gas ejected from the gas supply holes 17a of the third region 53, and the flow of the processing gas at the location corresponding to the second region 52. In the following description, the processing gas ejected from the gas supply holes 17 of the first region 51 will be properly referred to as a “first processing gas,” and the processing gas ejected from the gas supply holes 17a of the third region 53 will be properly referred to as a “second processing gas.” The first processing gas ejected from the gas supply holes 17 of the first region 51 to the space between the shower head 16 and the support table 2 flows in the exhaust direction [a direction in which the exhaust device 20 is connected]. The first processing gas flowing in the exhaust direction collides with the second processing gas ejected from the gas supply holes 17a of the third region 53 to the space between the shower head 16 and the support table 2. The second processing gas that is ejected from the gas supply holes 17a of the third region 53 to the space between the shower head 16 and the support table 2 is mixed with the processing gas guided to the gas supply holes 17a by a rectifying function of the second region 52. Therefore, the flow velocity of the second processing gas ejected from the gas supply holes 17a of the third region 53 to the space between the shower head 16 and the support table 2 is locally increased so that the second processing gas forms an airflow wall which interferes with the first processing gas flowing in the exhaust direction. Then, the speed of the first processing gas flowing in the exhaust direction is decreased in the space present at a location corresponding to the second region 52 interposed between the third region 53 and the first region 51, in the space between the shower head 16 and the support table 2. Here, each of the gas supply holes 17a of the third region 53 has the inclined portion 17a-1 which is inclined with respect to the central axis C of the wafer W so that a distance along the radial direction of the wafer W from the central axis C of the wafer W is increased as the inclined portion 17a-1 gets closer to the wafer W. Therefore, a gap between the first region 51 and the third region 53 becomes wider along the radial direction of the wafer W. As a result, the second region 52 becomes wider than the second region 52 in a case where the inclined portion 17a-1 is not present. Accordingly, the processing gas efficiently stays in the space present at the location corresponding to the second region 52 interposed between the third region 53 and the first region 51. As a result, plasma etching using the processing gas is further facilitated in the space present at the location corresponding to the second region 52 interposed between the third region 53 and the first region 51 in the space between the shower head 16 and the support table 2.

As described above, in the second exemplary embodiment, each of the gas supply holes 17a formed in the third region 53 of the electrode plate 18 has the inclined portion 17a-1 which is inclined with respect to the central axis C of the wafer W so that a distance along the radial direction of the wafer W from the central axis C of the wafer W is increased as the inclined portion 17a-1 gets closer to the wafer W. Therefore, plasma etching using the processing gas is further facilitated in the space present at the location corresponding to the second region 52 interposed between the third region 53 and the first region 51. As a result, according to the second exemplary embodiment, the controllability of the etching rate along the radial direction of the wafer W may be further improved.

Hereinafter, descriptions will be made on a simulation result by the plasma etching apparatus according to the second exemplary embodiment (a simulation result of a flow velocity distribution of the processing gas, and a simulation result of a pressure distribution of the processing gas).

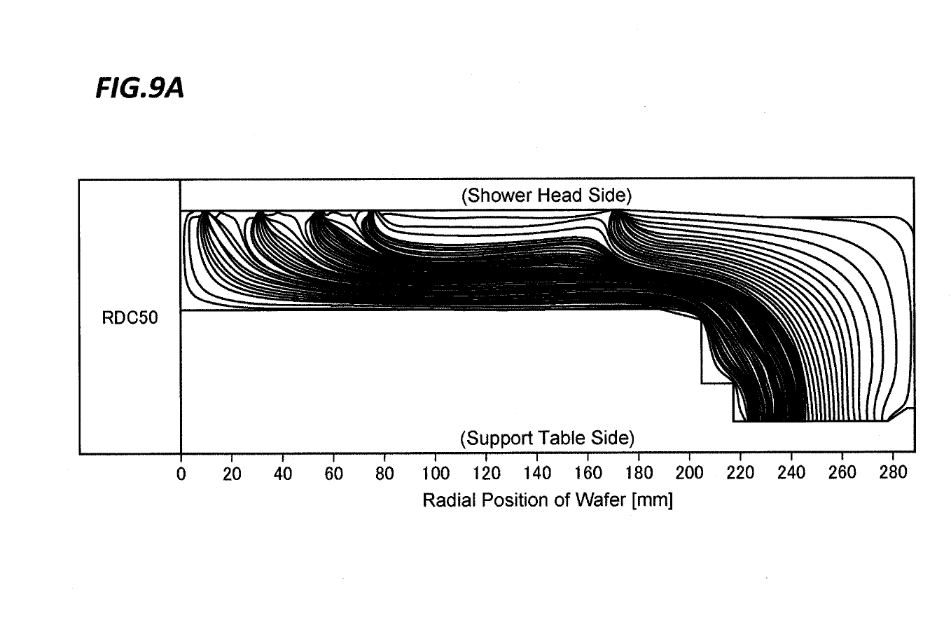

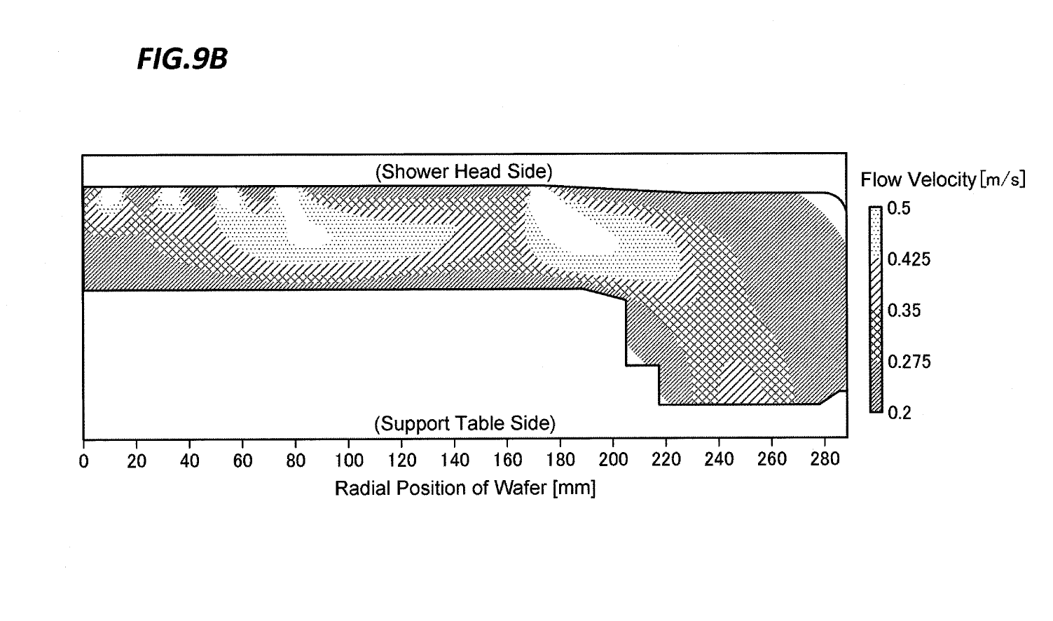

First, a simulation result of a flow velocity distribution of the processing gas will be described. FIG. 9A illustrates a streamline distribution of a processing gas with respect to a radial position of a wafer when the flow of the processing gas on the wafer was simulated using a plasma etching apparatus of the second exemplary embodiment. FIG. 9B illustrates a flow velocity distribution of a processing gas with respect to a radial position of a wafer when the flow of the processing gas on the wafer was simulated using the plasma etching apparatus of the second exemplary embodiment.

In the simulation of FIGS. 9A and 9B, a wafer with a radius of 150 mm was used, and the electrode plate 18 was divided into eight zones (Zones 1 to 8) along the radial direction from the center of the electrode plate 18. Then, among Zones 1 to 8, Zones 5 to 7 were closed, and the processing gas was ejected from Zones 1 to 4 and Zone 8 to obtain the streamline distribution of the processing gas and the flow velocity distribution of the processing gas. That is, in the simulation of FIGS. 9A and 9B, Zones 1 to 4 correspond to the first region 51, Zones 5 to 7 correspond to the second region 52, and Zone 8 corresponds to the third region 53. Also, in the simulation of FIGS. 9A and 9B, as for the gas supply holes 17 corresponding to Zone 1, four gas supply holes 17 were disposed on a circumference having a radius of 10 mm from the center of the electrode plate 18. As for the gas supply holes 17 corresponding to Zone 2, 12 gas supply holes 17 were disposed on a circumference having a radius of 30 mm from the center of the electrode plate 18. As for the gas supply holes 17 corresponding to Zone 3, 24 gas supply holes 17 were disposed on a circumference having a radius of 50 mm from the center of the electrode plate 18. As for the gas supply holes 17 corresponding to Zone 4, 36 gas supply holes 17 were disposed on a circumference having a radius of 70 mm from the center of the electrode plate 18. As for the gas supply holes 17 corresponding to Zone 5, 48 gas supply holes 17 were disposed on a circumference having a radius of 90 mm from the center of the electrode plate 18. As for the gas supply holes 17 corresponding to Zone 6, 60 gas supply holes 17 were disposed on a circumference having a radius of 110 mm from the center of the electrode plate 18. As for the gas supply holes 17 corresponding to Zone 7, 80 gas supply holes 17 were disposed on a circumference having a radius of 130 mm from the center of the electrode plate 18. As for the gas supply holes 17 corresponding to Zone 8, 100 gas supply holes 17 were disposed on a circumference having a radius of 150 mm from the center of the electrode plate 18.

Also, in the simulation of FIGS. 9A and 9B, it is assumed that the inclined portion 17a-1 is inclined at 25° with respect to the central axis C of the wafer W.

Also, in FIGS. 9A and 9B, the horizontal axis indicates a radial position [mm] of a wafer with respect to the center (0 mm) of the wafer with a radius of 150 mm.

Also, in FIGS. 9A and 9B, other simulation conditions are as follows: a processing gas:CF₄=150 sccm, a pressure within a chamber: 40 mTorr, and RDC: 50.

From FIGS. 9A and 9B, the following phenomenon was found. That is, in the plasma etching apparatus of the second exemplary embodiment, the processing gas ejected from the gas supply holes 17a corresponding to Zone 8 formed an airflow wall which interferes with the processing gas that is ejected from the gas supply holes 17 corresponding to Zones 1 to 4 and flows in the exhaust direction. Also, in the plasma etching apparatus of the second exemplary embodiment, the speed of the processing gas flowing in the exhaust direction was decreased in a space present at a location corresponding to the second region 52, in a space between the shower head 16 and the support table 2. Accordingly, in the apparatus of the exemplary embodiment in which the second region 52 not formed with the gas supply holes 17 is provided, the processing gas stayed in the space present at the location corresponding to the second region 52. Here, each of the gas supply holes 17a corresponding to Zone 8 has the inclined portion 17a-1 which is inclined with respect to the central axis C of the wafer W so that a distance along the radial direction of the wafer W from the central axis C of the wafer W is increased as the inclined portion 17a-1 gets closer to the wafer W. Therefore, a gap between the first region 51 and the third region 53 becomes wider along the radial direction of the wafer W. As a result, the second region 52 becomes wider than the second region 52 in a case where the inclined portion 17a-1 is not present. Accordingly, the processing gas efficiently stays in the space present at the location corresponding to the second region 52 interposed between the third region 53 and the first region 51. This is because in the space present at the location corresponding to the second region 52, the airflow wall formed by the processing gas ejected from the gas supply holes 17a corresponding to Zone 8 interferes with the flow of the processing gas to form retention of a gas flow. Accordingly, it is assumed that the retention increases the concentration of the processing gas (etchant gas), and facilitates plasma etching using the processing gas in the space present at the location corresponding to the second region 52 in the space between the shower head 16 and the support table 2. As a result, in the plasma etching apparatus of the second exemplary embodiment, it is assumed that it is possible to improve the controllability of the etching rate along the radial direction of the wafer W.

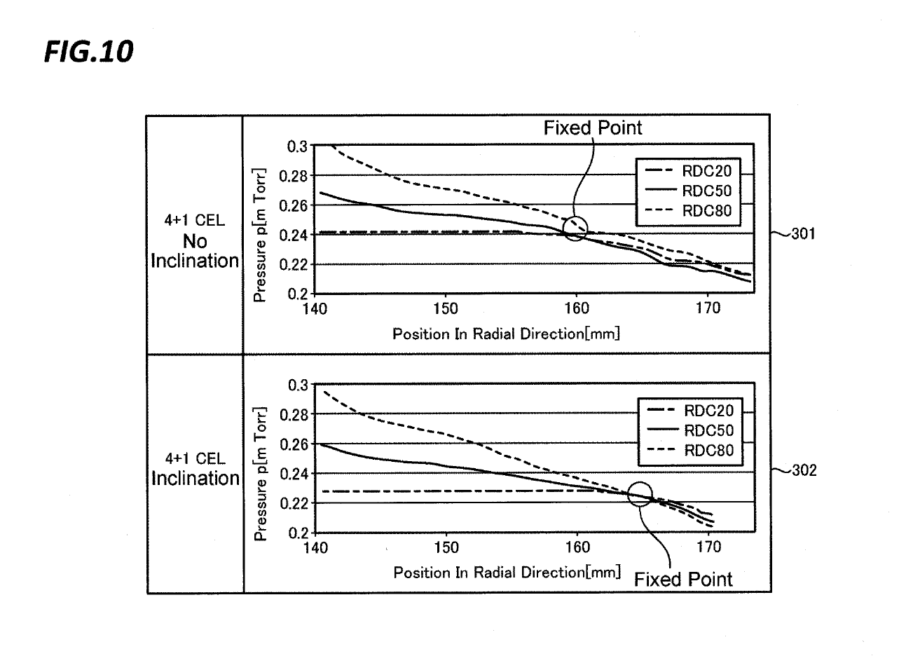

Subsequently, descriptions will be made on a simulation result of a pressure distribution of a processing gas. FIG. 10 is a view illustrating a simulation result on a pressure distribution of the processing gas in the plasma etching apparatus according to the second exemplary embodiment. FIG. 10 includes a graph 301 and a graph 302.

The graph 301 illustrates a simulation result when a pressure distribution of a processing gas on a wafer was simulated using a plasma etching apparatus of the first exemplary embodiment. The graph 302 illustrates a simulation result when a pressure distribution of a processing gas on a wafer was simulated using a plasma etching apparatus of the second exemplary embodiment. In the graphs 301 and 302, the vertical axis indicates a pressure [mTorr] at a position 5 mm above the front surface of the wafer. In the graphs 301 and 302, the horizontal axis indicates a radial position [mm] of a wafer with respect to the center (0 mm) of the wafer with a radius of 150 mm. In the graphs 301 and 302, the RDC indicates a ratio of a flow rate of a processing gas to be supplied to the first gas diffusion chamber 40a, to a flow rate of a processing gas to be supplied to the second gas diffusion chamber 40b.

Other simulation conditions are the same as those used in FIGS. 9A and 9B.

As illustrated in FIG. 10, as compared to that in the plasma etching apparatus of the first exemplary embodiment, the position where the pressure is fixed was shifted in the positive direction of the horizontal axis irrespective of RDC values in the plasma etching apparatus of the second exemplary embodiment. Also, as compared to that in the plasma etching apparatus of the first exemplary embodiment, the control width of the pressure distribution of the processing gas corresponding to the periphery portion of the wafer (that is, a position of 150 mm) was increased in the plasma etching apparatus of the second exemplary embodiment. That is, it was found that as in the second exemplary embodiment, when the inclined portion 17a-1 is provided in the gas supply holes 17a formed in the third region 53 of the electrode plate 18, the controllability of the pressure distribution of the processing gas is improved.

From the simulation result described above, it is assumed that when the inclined portion 17a-1 is provided in the gas supply holes 17a formed in the third region 53 of the electrode plate 18, the controllability of the etching rate along the radial direction of the wafer W may be improved.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container;
a support member provided within the processing container and configured to support a processing target substrate; and
a gas supply member including a first region formed with a gas supply hole, a second region not formed with a gas supply hole, and a third region formed with a gas supply hole, the first region, the second region, and the third region being disposed sequentially from a central portion side of the processing target substrate along a radial direction of the processing target substrate,
wherein the plasma processing apparatus is processed to introduce a processing gas from the gas supply holes of the gas supply member for plasma processing of the processing target substrate into the processing container.

2. The plasma processing apparatus of claim 1, wherein the gas supply hole formed in the third region is disposed at a position outside a position inwardly spaced apart from a periphery of the processing target substrate by 10 mm along the radial direction of the processing target substrate.

3. The plasma processing apparatus of claim 1, wherein the gas supply hole formed in the third region is disposed in a range from a position inwardly spaced apart from a periphery of the processing target substrate by 10 mm to a position outwardly spaced apart from the periphery of the processing target substrate by 10 mm along the radial direction of the processing target substrate.

4. The plasma processing apparatus of claim 1, wherein the gas supply hole formed in the third region is disposed at a position outside or on a periphery of the processing target substrate.

5. The plasma processing apparatus of claim 1, wherein the gas supply hole formed in the third region has an inclined portion that is inclined with respect to a central axis of the processing target substrate so that a distance along the radial direction of the processing target substrate from the central axis of the processing target substrate is increased as the inclined portion gets closer to the processing target substrate.

6. A gas supply member configured to supply a processing gas into a processing container in which a processing target substrate is disposed, the gas supply member comprising:
a first gas supply region disposed at a center portion side with respect to a central line between a central portion and an edge portion of the gas supply member, and formed with a plurality of first gas supply holes;
a second gas supply region disposed at an edge portion side with respect to the central line between the central portion and an edge portion of the gas supply member, and formed with a second gas supply hole; and
a non-gas supply region disposed between the first gas supply region and the second gas supply region, and not formed with a gas supply hole.

7. The gas supply member of claim 6, wherein the second gas supply hole is disposed at a position outside or on a periphery of the processing target substrate.

8. The gas supply member of claim 6, wherein the second gas supply hole has an inclined portion that is inclined with respect to a central axis of the processing target substrate so that a distance along the radial direction of the processing target substrate from the central axis of the processing target substrate is increased as the inclined portion gets closer to the processing target substrate.
